(19) United States
(12) Patent Application Publication
(10) Pub. No.: US 2018/0308890 A1
(43) Pub. Date: Oct. 25, 2018

(54) IMAGE SENSING CHIP PACKAGING STRUCTURE AND PACKAGING METHOD THEREFOR

(71) Applicant: China Wafer Level CSP Co., Ltd., Suzhou, Jiangsu (CN)

(72) Inventors: Zhiqi Wang, Suzhou, Jiangsu Province (CN); Zhijie Shen, Suzhou (CN); Jiawei Chen, Suzhou (CN)

(73) Assignee: China Wafer Level CSP Co., Ltd., Suzhou, Jiangsu (CN)

(21) Appl. No.: 15/767,623

(22) PCT Filed: Dec. 26, 2016
(86) PCT No.: PCT/CN2016/112080

§ 371 Date: Apr. 11, 2018

(30) Foreign Application Priority Data
Dec. 29, 2015 (CN) 201511008692.5
Dec. 29, 2015 (CN) 201521117238.9

(51) Int. Cl. H01L 27/146

(52) U.S. Cl. CPC H01L 27/14636; H01L 27/14625; H01L 27/14634; H01L 27/1469; H01L 27/14618; H01L 27/14689

(57) ABSTRACT

An image sensing chip packaging structure and a packaging method therefor. The image sensing chip packaging structure is provided with an image sensing chip and a control chip used for controlling the image sensing chip. The image sensing chip packaging structure also comprises a substrate, provided with a first surface and a second surface opposite to each other. The image sensing chip is electrically connected to the substrate, and is located on the first surface of the substrate. The control chip is electrically connected to the substrate, and is located on the second surface of the substrate. By applying a stacked packaging technology to the packaging of the image sensing chip, the size of the packaging structure of the image sensing chip is reduced, thereby improving the integration of the image sensing chip.

The present application claims priority to Chinese Patent Application No. 201511008692.5, titled “IMAGE SENSING CHIP PACKAGING STRUCTURE AND IMAGE SENSING CHIP PACKAGING METHOD” filed on Dec. 29, 2015 with the State Intellectual Property Office of People's Republic of China and Chinese Patent Application No. 201521117238.9, titled “IMAGE SENSING CHIP PACKAGING STRUCTURE” filed on Dec. 29, 2015 with the State Intellectual Property Office of People's Republic of China, both of which are incorporated herein by reference in their entireties.

### FIELD

The present disclosure relates to a packaging technology for a semiconductor chip, and in particular to a packaging technology for an image sensor chip.

### BACKGROUND

Image sensor chip serving as a functional chip for image acquisition is usually used in a camera of an electronic product. Benefiting from the continuous and vigorous development of camera phones, the market demands on image sensor chip keeps growing in the future. In addition, a considerable application scale of image sensor chips is also brought by prevalent network real-time communication services such as Skype, rise of security monitoring market and rapid development of global automotive electronics. Meanwhile, the packaging technology for the image sensor chip is also developed rapidly.

Package-on-package (POP) technology is one of popular three-dimensional stacking technologies which are developed for IC package of a mobile device such as a smart phone and a tablet computer and which can be applied to system integration.

How to apply the package-on-package technology to the field of image sensor chip packaging becomes the technical problem desired to be solved by those skilled in the art.

### SUMMARY

A new image sensor chip package and a new image sensor chip packaging method are provided according to the present disclosure, in which the package-on-package technology is applied to the image sensor chip packaging. In this way, a size of the image sensor chip package is reduced and an integration degree of an image sensor chip is improved.

An image sensor chip package is provided according to the present disclosure. The image sensor chip package includes an image sensor chip and a control chip configured to control the image sensor chip. The image sensor chip package further includes a substrate. The substrate includes a first surface and a second surface opposite to each other. The image sensor chip is electrically connected to the substrate and is arranged on the first surface of the substrate. The control chip is electrically connected to the substrate and is arranged on the second surface of the substrate.

Optionally, the image sensor chip includes a first surface and a second surface opposite to each other, the first surface of the image sensor chip is arranged with a photosensitive region and a contact pad on a region other than the photosensitive region, the second surface of the image sensor chip is arranged with a solder ball electrically connected to the contact pad, and the image sensor chip is electrically connected to the substrate via the solder ball.

Optionally, the first surface of the image sensor chip is covered by a protective cover plate, a sealed cavity is formed between the protective cover plate and the image sensor chip, and the photosensitive region is located in the sealed cavity.

Optionally, the protective cover plate is made of anti-reflective glass.

Optionally, the second surface of the substrate is arranged with a solder bump block for electrical connection with an external circuit, a height of the solder bump block is greater than a height of the control chip, and a space is formed between the control chip and the external circuit when the solder bump block is electrically connected to the external circuit.

Optionally, the control chip is electrically connected to the substrate with a flip-chip process.

Optionally, the control chip is electrically connected to the substrate via a solder wire.

An image sensor chip packaging method is further provided according to the present disclosure. The method includes: providing an image sensor chip and a control chip configured to control the image sensor chip; providing a substrate, with the substrate including a first surface and a second surface opposite to each other; connecting electrically the control chip to the second surface of the substrate; and connecting electrically the image sensor chip to the first surface of the substrate.

Optionally, before the connecting electrically the image sensor chip to the substrate, the method further includes: providing a wafer, where the wafer includes image sensor chips arranged in an array, each of the image sensor chips includes a first surface and a second surface opposite to each other, and the first surface of the image sensor chip is arranged with a photosensitive region and a contact pad on a region other than the photosensitive region; providing a protective cover plate with a same size as the wafer, where a surface of the protective cover plate is arranged with support units arranged in an array, and the support units correspond to the image sensor chips in a one-to-one manner; aligning and laminating the wafer with the protective cover plate, to form a sealed cavity between each of the image sensor chips and the protective cover plate, where the photosensitive region is located in the cavity; forming multiple through silicon vias on the second surface of the image sensor chip with a through silicon via process, where the through silicon vias correspond to contact pads in a one-to-one manner, and the contact pad is exposed from a bottom of the through silicon via; forming a metal wiring layer in the through silicon via, where the metal wiring layer is electrically connected to the contact pad; forming a solder ball on the second surface of the image sensor chip, where the solder ball is electrically connected to the metal wiring layer; and cutting the image sensor chip and the protective cover plate to separate the image sensor chips connected to each another.

Optionally, the protective cover plate is made of anti-reflective glass.

Optionally, the control chip is electrically connected to the substrate with a flip-chip process.

Optionally, the control chip is electrically connected to the substrate with a wire bonding process.

Optionally, a solder bump block for electrical connection with an external circuit is arranged on the second surface of the substrate, a height of the solder bump block is greater than a height of the control chip, and a space is formed between the control chip and the external circuit when the solder bump block is electrically connected to the external circuit.

The new image sensor chip package and the new image sensor chip packaging method are provided according to the embodiments of the present disclosure, in which the package-on-package technology is applied to the image sensor chip packaging. In this way, the size of the image sensor chip package is reduced and the integration degree of the image sending chip is improved.

### BRIEF DESCRIPTION OF THE DRAWINGS

FIG. 1 is a schematic diagram of an image sensor chip package according to an embodiment of the present disclosure; and

FIGS. 2(a) to 2(g) are schematic diagrams showing a process of packaging an image sensor chip according to an embodiment of the present disclosure.

### DETAILED DESCRIPTION OF EMBODIMENTS

Hereinafter, embodiments of the present disclosure are described in detail in conjunction with the drawings. The embodiments are not intended to limit the present disclosure, and transformations made by those skilled in the art in structure, method or function based on these embodiments all fall within the scope of protection of the present disclosure.

It should be noted that, the provided drawings are only for helping to understand the embodiments of the present disclosure, and should not be explained to inappropriately limit the present disclosure. For clarity, the size shown in the drawings is not drawn to scale, and may be zoomed in, zoomed out and changed in other manners. In addition, a three-dimensional size containing length, width and depth should be included in an actual fabrication.

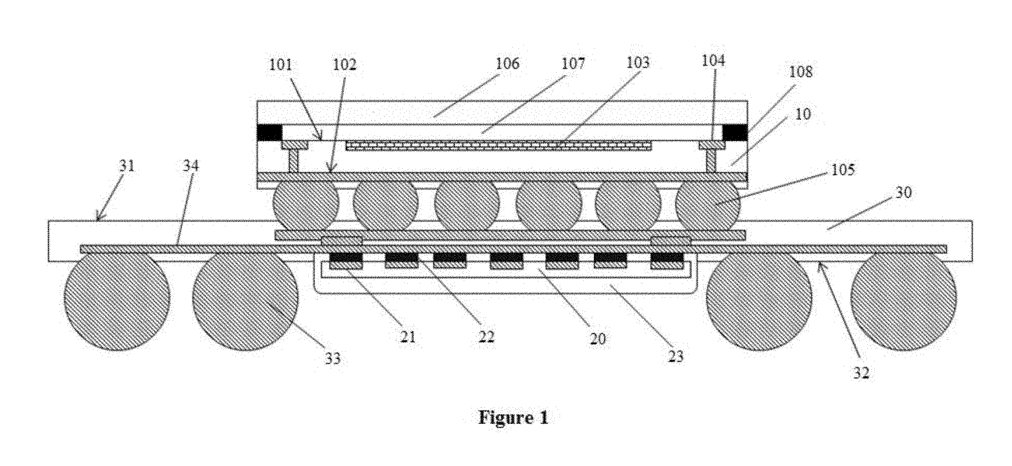

Referring to FIG. 1, FIG. 1 is a schematic diagram of an image sensor chip package according to an embodiment of the present disclosure. An image sensor chip package includes an image sensor chip 10, a control chip 20 and a substrate 30. The substrate 30 includes a first surface 31 and a second surface 32 opposite to each other. The image sensor chip 10 is electrically connected to the substrate 30 and is arranged on the first surface 31 of the substrate 30. The control chip 20 is electrically connected to the substrate 30 and is arranged on the second surface 31 of the substrate 30. The image sensor chip 10 is opposite to the control chip 20. In this way, it is formed a package-on-package structure for the image sensor chip.

With the package-on-package structure, the image sensor chip has an improved integration degree and a reduced package size.

The image sensor chip 10 is a semiconductor chip having at least an image sensing unit. The image sensing unit may be a CMOS sensor or CCD sensor. The image sensor chip 10 may further include an associative circuit connected to the image sensing unit.

The control chip 20 is configured to control the image sensor chip 10. The function of the control chip 20 is not limited herein, as long as an electric signal is transmitted between the control chip 20 and the image sensor chip 10, that is, the “control” herein can be achieved. In an implementation, the substrate 30 is arranged with an electrical interconnection structure 34, and the image sensor chip 10 is electrically connected to the control chip 20 via the electrical interconnection structure 34.

The image sensor chip 10 in the embodiment is a semiconductor chip having a CMOS sensor. The image sensor chip 10 includes a first surface 101 and a second surface 102 opposite to each other. A photosensitive region 103 and a contact pad 104 on a region other than the photosensitive region 103 are arranged on the first surface 101. The contact pad 104 is electrically connected to the photosensitive region 103 (not shown in FIG. 1).

The image sensor chip 10 is electrically connected to the substrate 30 and is arranged on the first surface 31 of the substrate 30. A solder ball 105 is formed on the second surface 102 of the image sensor chip 10 and the solder ball 105 is electrically connected to the contact pad 104. The image sensor chip 10 is electrically connected to the substrate 30 by welding the solder ball 105 with the substrate 30.

In order to protect the image sensor chip 10 and prevent the photosensitive region 103 from being contaminated by dusts and the like, the first surface 101 of the image sensor chip 10 is covered by a protective cover plate 106. In this case, a sealed cavity 107 is formed between the protective cover plate 106 and the image sensor chip 10, and the photosensitive region 103 is located in the cavity 107 and is prevented from being contaminated by dusts and the like. In the embodiment, a support unit 108 is formed on a surface of the protective cover plate 106. The support unit 108 is located between the protective cover plate 106 and the image sensor chip 10, and the cavity 107 is surrounded by the support unit 108, the protective cover plate 106 and the image sensor chip 10.

The protective cover plate 106 is made of light-transmissive material. In an implementation, the protective cover plate 106 is made of anti-reflective glass which has a good light transmission, thereby facilitating projection of light to the photosensitive region 103.

In an implementation, the support unit 108 is made of photoresist, and is formed on the surface of the protective cover plate 106 with an exposure developing process.

The control chip 20 is electrically connected to the substrate 30 and is arranged on the second surface 32 of the substrate 30. The control chip 20 is arranged with multiple electrical connection pads 21, a solder bump spot 22 is formed on the electrical connection pad 21. The solder bump spot 22 may be made of gold, tin-lead or other lead-free metal material. The electrical connection pad 21 is electrically connected to the substrate 30 via the solder bump spot 22 with a flip-chip process, to electrically connect the control chip 20 with the substrate 30.

In another embodiment, the control chip 20 is electrically connected to the substrate 30 in a wire bonding manner, that is, the control chip 20 is electrically connected to the substrate 30 via a solder wire. The solder wire may be made of metal material including copper, tungsten, aluminum, gold, silver and the like. Furthermore, a package is formed by packaging the control chip 20 and the solder wire, to protect the control chip 20 and the solder wire.

In an implementation, the substrate 30 is made of plastic material. An underfill process may be introduced in the process of electrically connecting the image sensor chip 10 and the control chip 20 to the substrate 30, to eliminate affect from stress. As shown in FIG. 1, an underfill glue 23 is filled in a space between the control chip 10 and the substrate 30, and the control chip 20 is also enclosed by the underfill glue 23.

For electrical connection between the image sensor chip package and other external circuits, the second surface 32 of the substrate 30 is arranged with a solder bump block 33 for the electrical connection with the external circuit. A height of the solder bump block 33 is greater than a height of the control chip 20, such that a space is formed between the control chip 20 and the external circuit when the solder bump 33 is electrically connected to the external circuit.

The electrical interconnection structure 34 is arranged on the substrate 30. The image sensor chip 10, the control chip 20 and the solder bump block 33 are electrically connected to each another via the electrical interconnection structure 34.

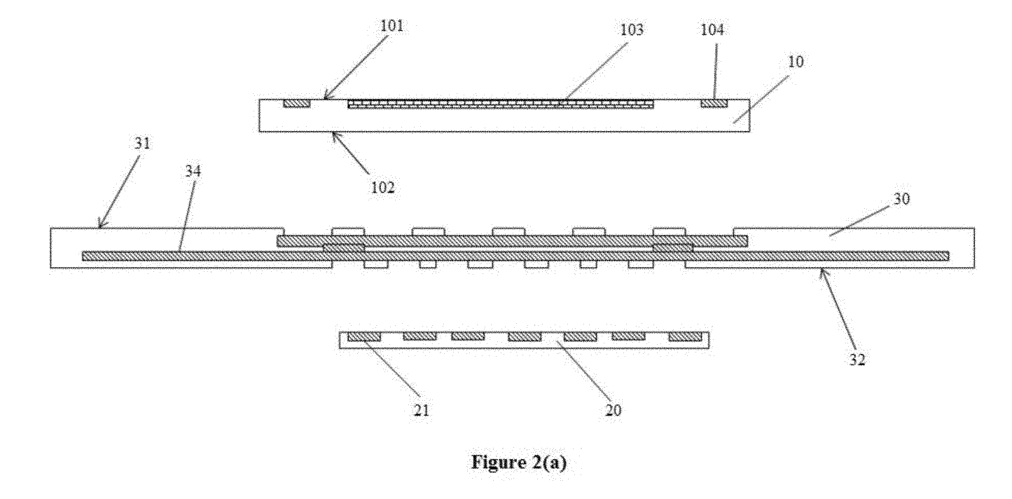

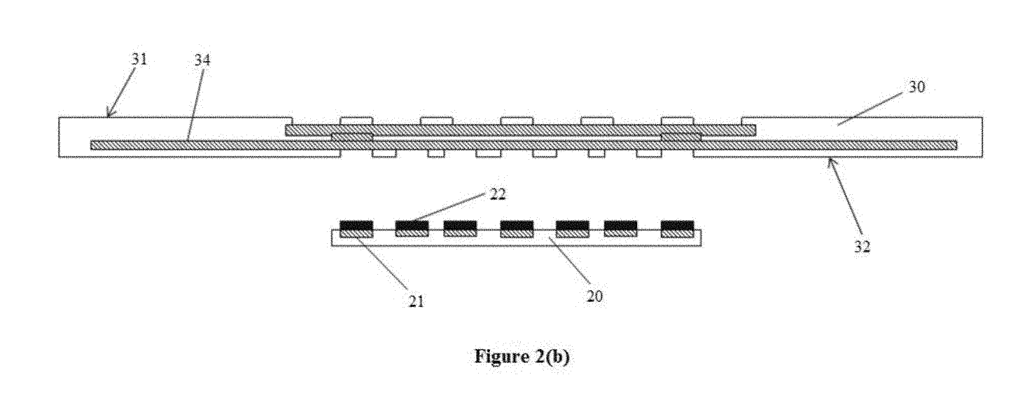

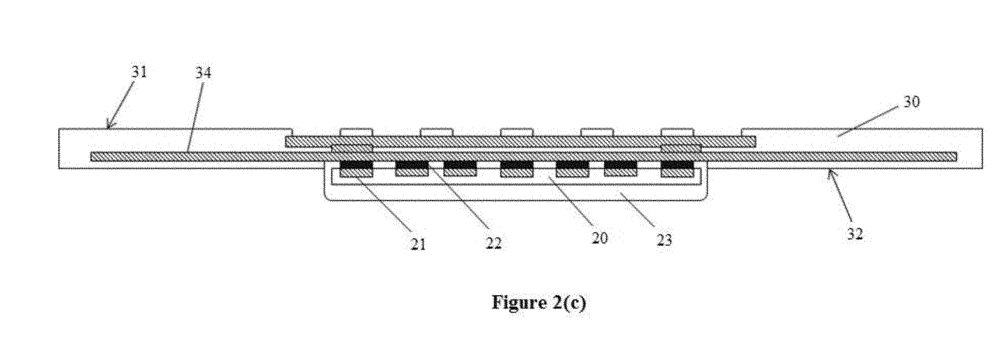

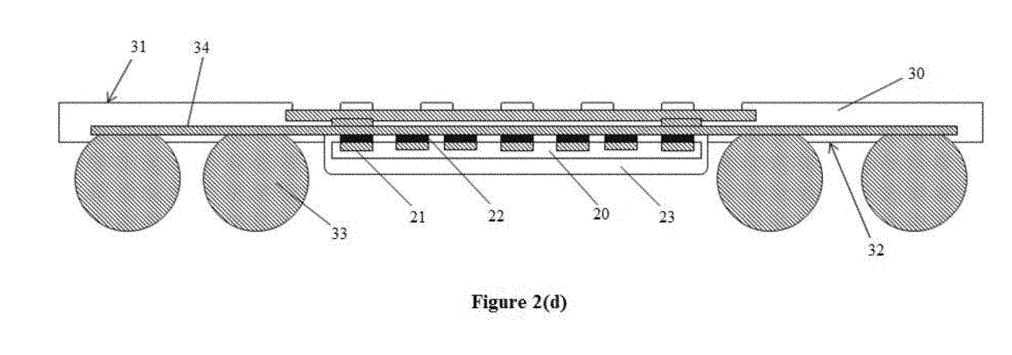

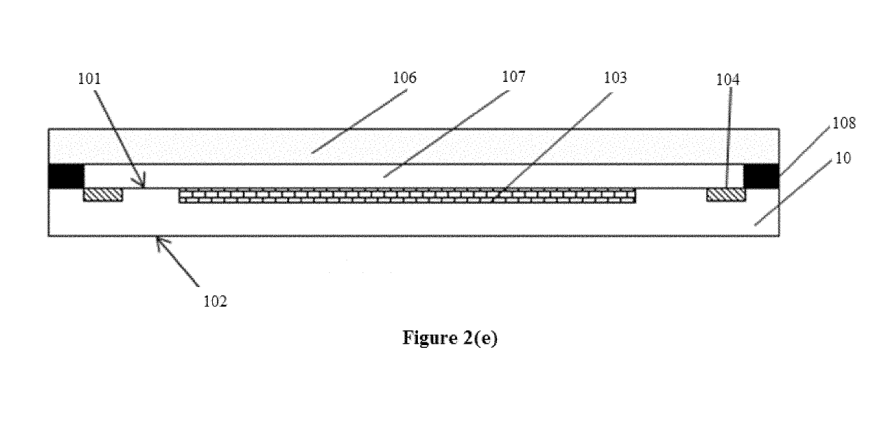

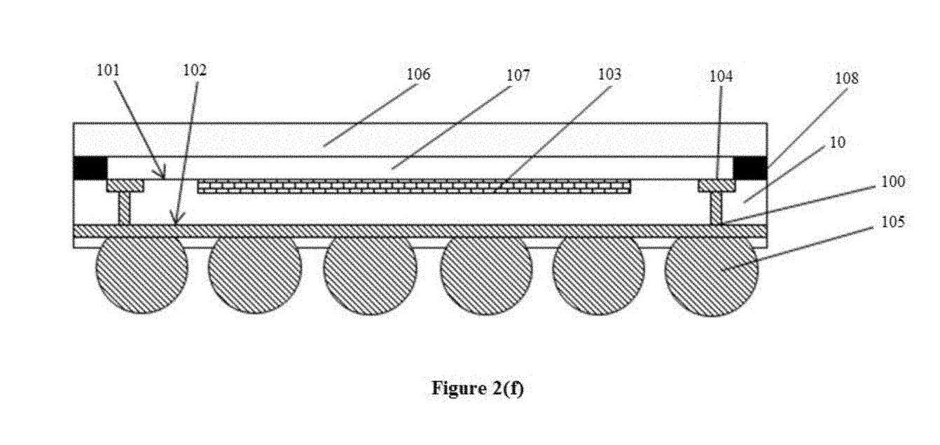

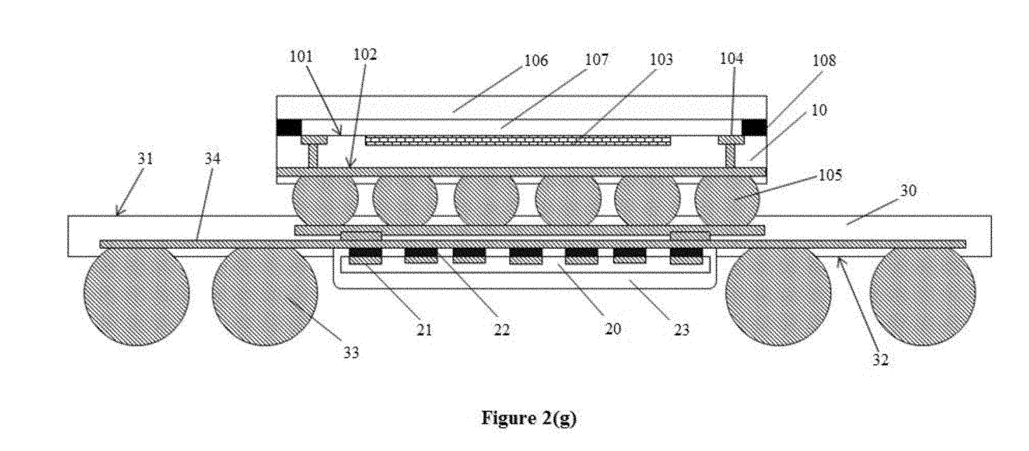

FIGS. 2(a) to 2(f) are schematic diagrams showing a process of packaging an image sensor chip according to an embodiment of the present disclosure.

Referring to FIG. 2(a), an image sensor chip 10, a control chip 20, and a substrate 30 are provided. The control chip 20 is configured to control the image sensor chip 10, and the substrate 30 has a first surface 31 and a second surface 32 opposite to each other.

Referring to FIG. 2(b), the control chip 20 is electrically connected to the second surface 32 of the substrate 30. The control chip 20 includes multiple electrical connection pads 21, a solder bump spot 22 is formed on the electrical connection pads 21. The solder bump spot 22 may be made of gold, tin-lead or other lead-free metal material. The electrical connection pad 21 is electrically connected to the substrate 30 via the solder bump spot 22 with a flip-chip process, thereby electrically connecting the control chip 20 with the substrate 30.

Referring to FIG. 2(c), an underfill process is adopted to fill a space between the control chip 10 and the substrate 30 with an underfill glue 23, and enclose the control chip 20 with the underfill glue 23.

In another embodiment, the control chip 20 is electrically connected to the substrate 30 in a wire bonding manner, that is, the control chip 20 is electrically connected to the substrate 30 via a solder wire. The solder wire may be made of metal material including copper, tungsten, aluminum, gold, silver and the like. Furthermore, a package is formed by packaging the control chip 20 and the solder wire, to protect the control chip 20 and the solder wire.

Referring to FIG. 2(d), after the control chip is electrically connected to the second surface of the substrate and before the image sensor chip is electrically connected to the first surface of the substrate, a solder bump block 33 for electrical connection with an external circuit is arranged on the second surface 32 of the substrate 30 with a soldering ball process. A height of the solder bump block 33 is greater than a height of the control chip 20, such that a space is formed between the control chip 20 and the external circuit when the solder bump block 33 is electrically connected to the external circuit.

Referring to FIG. 2(e), the image sensor chip 10 is covered by a protective cover plate 106.

The image sensor chip 10 in the embodiment is a semiconductor chip having a CMOS sensor. The image sensor chip 10 includes a first surface 101 and a second surface 102 opposite to each other. The first surface 101 is arranged with a photosensitive region 103 and a contact pad 104 on a region other than the photosensitive region 103. The contact pad 104 is electrically connected to the photosensitive region 103.

Specifically, the process in FIG. 2(e) includes the following steps.

It is provided a wafer including image sensor chips 10 arranged in an array.

It is provided the protective cover plate 106 with a same size as the wafer. On a surface of the protective cover plate, support units 108 are formed and arranged in an array. The support units 108 correspond to the image sensor chips 10 in a one-to-one manner.

The protective cover plate 106 is aligned with and laminated on the first surface 101 of the image sensor chip 10, and the support unit 108 is located between the protective cover plate 106 and the image sensor chip 10. In this case, a sealed cavity 107 is formed between the protective cover plate 106 and each of the image sensor chips 10. In this case, the photosensitive region 103 is located in the cavity 107 and is prevented from being contaminated by dusts and the like.

The protective cover plate 106 is made of light-transmissive material. In an implementation, the protective cover plate 106 is made of anti-reflective glass which has a good light transmission, thereby facilitating projection of light to the photosensitive region 103.

The support unit 108 may be made of photoresist.

Referring to FIG. 2(f), a solder ball 105 is formed on the second surface 102 of the image sensor chip 10 and the solder ball 105 is electrically connected to the contact pad 104. Specifically, multiple through silicon vias are formed on the second surface 102 of the image sensor chip 10 with a through silicon via process. The through silicon vias correspond to the contact pads 104 in a one-to-one manner. The contact pad 104 is exposed from a bottom of the through silicon via. A metal wiring layer 100 is formed in the through silicon via and is electrically connected to the contact pad 104. The metal wiring layer 100 extends to the second surface 102 of the image sensor chip 10. The solder ball 105 is formed on the second surface 102 of the image sensor chip 10 and is electrically connected to the metal wiring layer 100.

The wafer and the protective cover plate are cut, to separate the multiple image sensor chips 10 connected to each another.

Referring to FIG. 2(g), the image sensor chip 10 is electrically connected to the first surface 31 of the substrate 30 by welding the solder ball 105 with the substrate 30, to connect electrically the image sensor chip 10 to the substrate 30. The image sensor chip 10 is opposite to the control chip 20.

In the embodiment, the new image sensor chip package and the new image sensor chip packaging method are provided according to the present disclosure, in which the package-on-package technology is applied to the image sensor chip packaging. In this way, the size of the image sensor chip package is reduced and the integration degree of the image sending chip is improved.

It should be understood that, although the present disclosure is described with embodiments, it is not indicated that each embodiment only includes one independent technical solution. The specification is described in the above way, only for clarity. Those skilled in the art should take the specification as an whole, and other embodiments understandable to those skilled in the art may be formed by appropriately combine the technical solutions of these embodiments.

The above series of detailed descriptions are only descriptions of practicable embodiments of the present disclosure, and are not intended to limit the scope of protection of the present disclosure. Any equivalent embodiment or changes made without departing from the spirit of the present disclosure shall fall within the scope of protection of the present disclosure.

1. An image sensor chip package, comprising:
an image sensor chip;
a control chip configured to control the image sensor chip; and
a substrate comprising a first surface and a second surface opposite to each other, wherein
the image sensor chip is electrically connected to the substrate and is arranged on the first surface of the substrate; and
the control chip is electrically connected to the substrate and is arranged on the second surface of the substrate.

2. The image sensor chip package according to claim 1, wherein the image sensor chip comprises a first surface and a second surface opposite to each other, the first surface of the image sensor chip is arranged with a photosensitive region and a contact pad on a region other than the photosensitive region, the second surface of the image sensor chip is arranged with a solder ball electrically connected to the contact pad, and the image sensor chip is electrically connected to the substrate via the solder ball.

3. The image sensor chip package according to claim 2, wherein the first surface of the image sensor chip is covered by a protective cover plate, a sealed cavity is formed between the protective cover plate and the image sensor chip, and the photosensitive region is located in the sealed cavity.

4. The image sensor chip package according to claim 3, wherein the protective cover plate is made of anti-reflective glass.

5. The image sensor chip package according to claim 1, wherein the second surface of the substrate is arranged with a solder bump block for electrical connection with an external circuit, a height of the solder bump block is greater than a height of the control chip, and a space is formed between the control chip and the external circuit when the solder bump block is electrically connected to the external circuit.

6. The image sensor chip package according to claim 1, wherein the control chip is electrically connected to the substrate with a flip-chip process.

7. The image sensor chip package according to claim 1, wherein the control chip is electrically connected to the substrate via a solder wire.

8. An image sensor chip packaging method, comprising:
providing an image sensor chip and a control chip configured to control the image sensor chip;
providing a substrate, with the substrate comprising a first surface and a second surface opposite to each other;
connecting electrically the control chip to the second surface of the substrate; and
connecting electrically the image sensor chip to the first surface of the substrate.

9. The image sensor chip packaging method according to claim 8, wherein, before the connecting electrically the image sensor chip to the substrate, the method further comprises:
providing a wafer, wherein the wafer comprises image sensor chips arranged in an array, each of the image sensor chips comprises a first surface and a second surface opposite to each other, and the first surface of the image sensor chip is arranged with a photosensitive region and a contact pad on a region other than the photosensitive region;
providing a protective cover plate with a same size as the wafer, wherein a surface of the protective cover plate is arranged with support units arranged in an array, and the support units correspond to the image sensor chips in a one-to-one manner;
aligning and laminating the wafer with the protective cover plate, to form a sealed cavity between each of the image sensor chips and the protective cover plate, wherein the photosensitive region is located in the cavity;
forming a plurality of through silicon vias on the second surface of the image sensor chip with a through silicon via process, wherein the through silicon vias correspond to contact pads in a one-to-one manner, and the contact pad is exposed from a bottom of the through silicon via;
forming a metal wiring layer in the through silicon via, wherein the metal wiring layer is electrically connected to the contact pad;
forming a solder ball on the second surface of the image sensor chip, wherein the solder ball is electrically connected to the metal wiring layer; and
cutting the wafer and the protective cover plate to separate the image sensor chips connected to each another.

10. The image sensor chip packaging method according to claim 9, wherein the protective cover plate is made of anti-reflective glass.

11. The image sensor chip packaging method according to claim 8, wherein the control chip is electrically connected to the substrate with a flip-chip process.

12. The image sensor chip packaging method according to claim 8, wherein the control chip is electrically connected to the substrate with a wire bonding process.

13. The image sensor chip packaging method according to claim 8, further comprising: arranging a solder bump block for electrical connection with an external circuit on the second surface of the substrate, a height of the solder bump block is greater than a height of the control chip, and a space is formed between the control chip and the external circuit when the solder bump block is electrically connected to the external circuit.
